(19) United States
(12) Patent Application Publication
(10) Pub. No.: US 2024/0380142 A1
(43) Pub. Date: Nov. 14, 2024

(54) Joint, Electrical Assembly, Electrical Measurement Device and Manufacturing Method

(71) Applicant: TE Connectivity Solutions GmbH, Schaffhausen (CH)

(72) Inventors: Simon Scherner, Speyer (DE); Peter Zawadzky, Speyer (DE); Karlheinz Glaser, Bensheim (DE); Marcus Eberle, Speyer (DE); Hamdi Karabiyik, Speyer (DE)

(73) Assignee: TE Connectivity Solutions GmbH, Schaffhausen (CH)

(21) Appl. No.: 18/660,842

(22) Filed: May 10, 2024

(30) Foreign Application Priority Data
May 11, 2023 (EP) 23172865.0

(51) Int. Cl. H01R 12/58; H01R 13/04; H01R 13/10; H01R 13/35; H01R 43/02

(52) U.S. Cl. CPC H01R 12/585; H01R 13/04; H01R 13/10; H01R 13/35; H01R 43/0256; H01R 2201/20

(57) ABSTRACT

A joint for attaching a printed circuit board to an electrical conductor includes an electrically conductive lining that lines an inner surface of a through-hole in the printed circuit board and a tenon pressed in the through-hole. The tenon is in frictional and electrical contact with the electrically conductive lining. The tenon is monolithically formed from a material of the electrical conductor.

### CROSS-REFERENCE TO RELATED APPLICATION

This application claims the benefit of the filing date under 35 U.S.C. § 119 (a)-(d) of European Patent Application No. 23172865.0, filed on May 11, 2023.

### FIELD OF THE INVENTION

The present invention relates to a joint for attaching or mounting a printed circuit board (PCB) to a solid electrical conductor.

### BACKGROUND

For many applications in the field of electrical engineering, printed circuit boards of electrical devices need to be attached to solid electrical conductors. Conventionally, this kind of attachment is established by arranging a separate connection element between the printed circuit board and the solid electrical conductor.

Not only is said connection element an additional part that requires handling, but it also usually produces scrap during its manufacturing. Moreover, said connection element must be welded, soldered, glued, screwed, or otherwise mechanically fixated to the solid electrical conductor. This imposes certain restrictions on the choice of material with regard to aspects such as weldability and solderability. The necessary mechanical fixation of the connection element also results in additional interconnections that might fail after a certain time. The risk of such a failure increases, for example, if a high vibration load is to be expected.

### SUMMARY

A joint for attaching a printed circuit board to an electrical conductor includes an electrically conductive lining that lines an inner surface of a through-hole in the printed circuit board and a tenon pressed in the through-hole. The tenon is in frictional and electrical contact with the electrically conductive lining. The tenon is monolithically formed from a material of the electrical conductor.

### BRIEF DESCRIPTION OF THE DRAWINGS

Features of the present invention will become more apparent by describing in detail exemplary embodiments thereof with reference to the accompanying drawings, in which:

FIG. 1 shows a schematic representation of an exploded view of an electrical measurement device according to an embodiment of the present disclosure;

FIG. 2 shows a schematic representation of an exploded sectional view of an electrical assembly according to a first embodiment of the present disclosure;

FIG. 3 shows a schematic representation of a sectional view of the electrical assembly from FIG. 2;

FIG. 4 shows a schematic representation of a top view of the electrical assembly from FIG. 2;

FIG. 5 shows a schematic representation of a top view of an electrical assembly according to a second embodiment of the present disclosure;

FIG. 6 shows a schematic representation of a top view of an electrical assembly according to a third embodiment of the present disclosure;

FIG. 7 shows a schematic representation of a top view of an electrical assembly according to a fourth embodiment of the present disclosure;

FIG. 8 shows a schematic representation of a top view of an electrical assembly according to a fifth embodiment of the present disclosure;

FIG. 9 shows a schematic representation of a top view of an electrical assembly according to a sixth embodiment of the present disclosure;

FIG. 10 shows a schematic representation of a top view of an electrical assembly according to a seventh embodiment of the present disclosure;

FIG. 11 shows a schematic representation of a perspective view of a solid electrical conductor according to an embodiment of the present disclosure;

FIG. 12 shows a schematic representation of a detail XII of FIG. 11;

FIG. 13 shows a schematic representation of a perspective view of a tenon and elevation according to an embodiment of the present disclosure;

FIG. 14 shows a schematic representation of a perspective view of a tenon and elevation according to another embodiment of the present disclosure; and

FIG. 15 shows a schematic representation of an exploded view of an electrical assembly according to an eighth embodiment of the present disclosure.

### DETAILED DESCRIPTION OF EMBODIMENTS

In the following, exemplary embodiments of the invention are described with reference to the drawings. The embodiments described and shown in the drawings are for explanatory purposes only. The combination of features shown in the embodiments may be changed. For example, a feature which is not shown in an embodiment may be added if the technical effect associated with this feature is beneficial for a particular application. Vice versa, a feature shown as part of an embodiment may be omitted if the technical effect associated with this feature is not needed in a particular application. In the drawings, elements that correspond to each other with respect to function and/or structure have been provided with the same reference numeral.

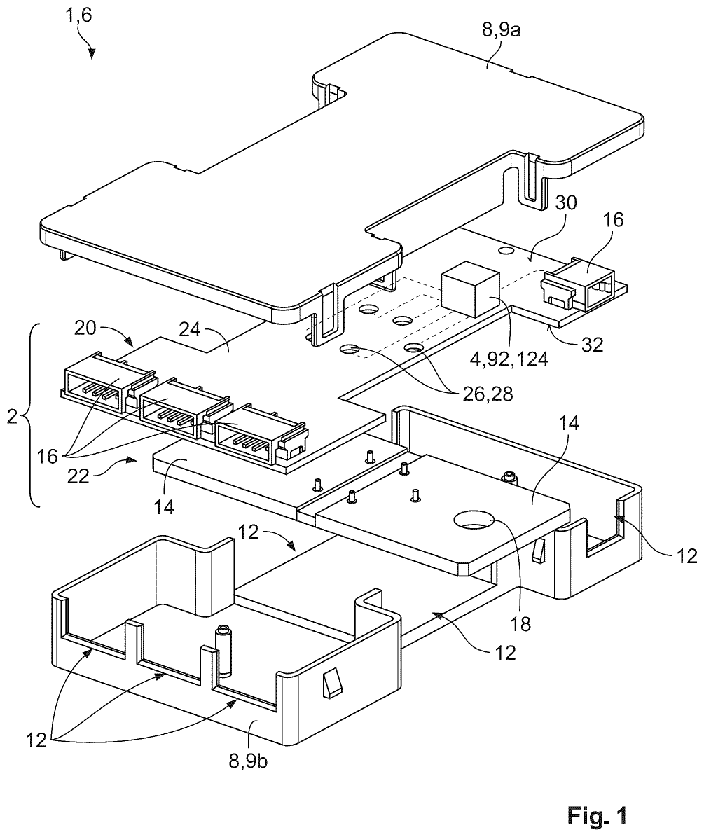

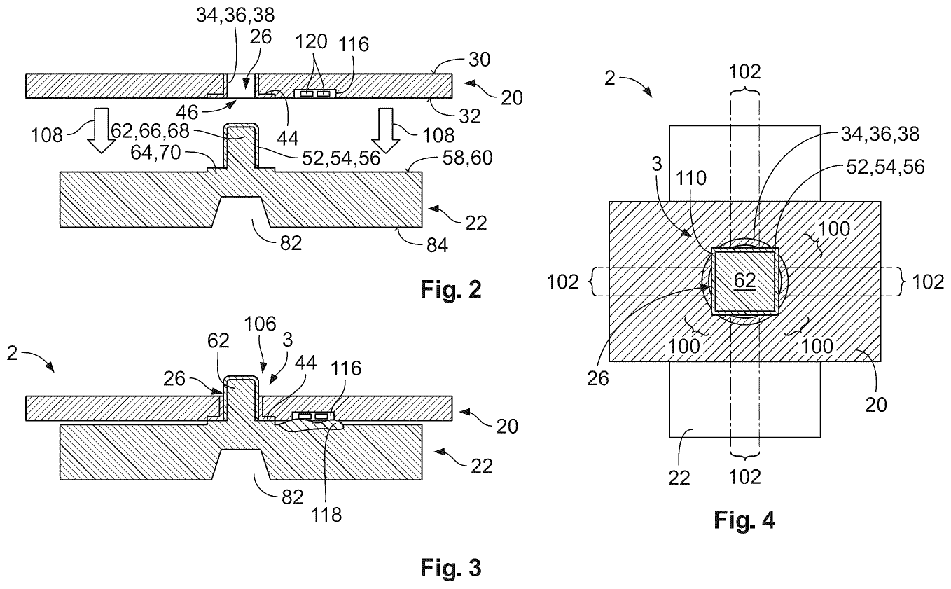

First, the structure of a possible embodiment of an electrical measurement device 1 according to the present invention is explained with reference to FIG. 1. Next, FIGS. 2 to 15 are used to explain the structure of possible embodiments of an electrical assembly 2 and a joint 3, respectively. Lastly, a manufacturing method according to the present invention is explained with reference to FIGS. 2 to 4.

FIG. 1 shows an exploded view of the electrical measurement device 1 according to one possible embodiment of the present disclosure. The electrical measurement device 1 comprises the electrical assembly 2 and an electrical sensor 4, which is connected to the electrical assembly 2. An example of an electrical sensor 4 may be or comprise of a voltmeter 92 or any type of signal conditioning device 124. In this specific embodiment, the electrical measurement device 1 may, for example, be used as an active shunt 6 for the measurement of electrical currents. This will be explained further below.

Moreover, the electrical measurement device 1 may comprise a housing 8 in which the electrical assembly 2 and the electrical sensor 4 are accommodated. In the shown embodiment of FIG. 1, a housing 8 comprised of two housing halves 9a, 9b is provided. The housing halves 9a, 9b may be configured to be clipped together. Alternatively, the housing halves 9a, 9b may also be glued, welded, soldered, or screwed together. Further, a partial or complete overmolding of the electrical measurement device 1 with a thermoand/or duroplastic material is also possible.

Further, the housing 8 may have one or more access openings 12. Through these access openings 12, the electrical assembly 2 may be accessible from outside the housing 8. For example, the connection terminals 14 and/or card-edge connectors 16 of the electrical assembly 2 may extend through the access openings 12 or at least be aligned with the access openings 12 inside the housing 8. The connection terminals 14 may be plate-shaped and each comprise a screw hole 18 for passing a screw. The corresponding screw may be an optional part of the electrical measurement device 1.

In FIG. 2, an exploded sectional view of a possible embodiment of the electrical assembly 2 is shown. As can be seen, the electrical assembly 2 comprises a printed circuit board 20 and a solid electrical conductor 22. The printed circuit board 20 is attached to the solid electrical conductor 22 by the joint 3 (see FIG. 3).

The printed circuit board 20 may comprise a substrate 24 made of glass-reinforced epoxy laminate material, in particular of the category FR-4 according to NEMA LI 1-1998 standard. With this choice of substrate material, the printed circuit board 20 can withstand the forces acting at the at least one through-hole 26 and at the electrically conductive lining. Through the substrate of the printed circuit board 20, at least one through-hole 26, in particular a via 28 (vertical interconnect access) may extend. As such, the at least one through-hole 26 may connect a top side 30 of the printed circuit board 20 with a bottom side 32 of the printed circuit board 20.

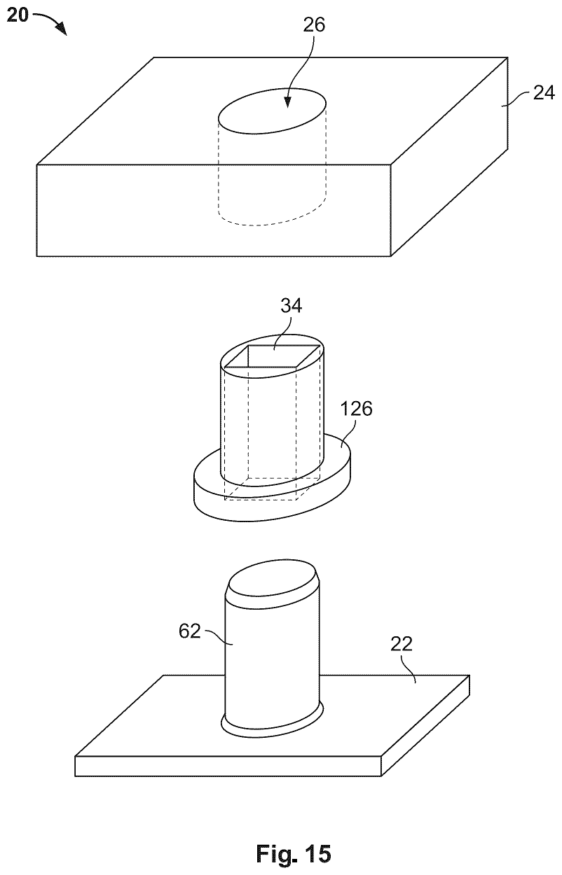

The at least one through-hole 26 may comprise an electrically conductive lining 34. In particular, the electrically conductive lining 34 may be achieved through a metallic plating 36, metallic coating 38 and/or metallic insert sleeve 126 (see FIG. 15) within the at least one through-hole 26. If a tenon 62 has the circular cross section, an inner cross section of the insert sleeve 126 may have the shape of a square, rectangle, triangle, polygon, oval, ellipse, clover, cross or any other non-circular regular or irregular geometric form. For a tenon 62 with the non-circular cross section, the inner cross section of the insert sleeve 126 may be circular. The sleeve may have inwardly extending spikes, ribs, knobs, or other convex protrusions to arrive at a non-circular cross section of the lining.

On the bottom side 32, the printed circuit board 20 may comprise at least one electrically conductive trace 44 extending at least sectionally around the at least one through-hole 26, in particular around an opening 46 of the at least one through-hole 26. The at least one electrically conductive trace 44 may extend continuously or discontinuously around the at least one through-hole 26. In an embodiment, the electrically conductive lining 34 and the at least one electrically conductive trace 44 are electrically interconnected.

The solid electrical conductor 22 may be a busbar 48, a shunt 50 or any other type of conductor massively made of electrically conductive material. For example, the solid electrical conductor 22 may be made of copper, copper alloy, in particular copper wrought alloy, aluminum, aluminum alloy, stainless steel or any other metallic or metallized material with a ductility suitable for coining, stamping, pressing, punching, embossing and/or similar processes. Optionally, the solid electrical conductor 22 may at least in sections comprise a coating 52, plating 54 or brazing 56 of a rare metal (e.g., silver) or a rare metal alloy.

The coating 52 may be a plasma coating; a plating, in particular a chemical plating or electro-plating; a brazing; a cladding or any other type of metal application to its surface. The applied metal may be a rare and/or precious and/or typical conductive metal (e.g., silver) or a rare and/or precious and/or typical conductive metal alloy for reduced contact resistance. The metal may be applied entirely or only partly on the solid electrical conductor 22. For example, a Sn metallization via plasma may be applied to the outer surface of the at least one tenon 62, while the remaining surface of the solid electrical conductor 22 may be left untreated.

Further, the solid electrical conductor 22 may be substantially flat or have at least one flat side 58. Said flat side 58 may be facing towards the bottom side 32 of the printed circuit board 20 and may be referred to as a top side 60 of the solid electrical conductor 22. On said top side 60, at least one tenon 62 may be monolithically formed from the material of the solid electrical conductor 22. In an embodiment, at least one elevation 64 extending around the at least one tenon 62 may also be monolithically formed from the material of the solid electrical conductor 22.

The monolithic formation of the tenon 62 eliminates the necessity for any separate fixation element. The absence of separate fixation elements results in less scrap being produced and less parts being required for the attachment of the printed circuit board 20 to the solid electrical conductor 22. Less parts also means that less boundary areas between the parts are present in the joint 3, leading to a lower electrical transfer resistance. Hence, any electrical assembly utilizing the joint 3 will not only be improved from an economic viewpoint but will also exhibit better performance during its operation compared to a conventional electrical assembly with a separate connection element. In an electrical assembly for measurement applications, fewer interconnections along the measurement path are present, therefore reducing the Failures In Time (FIT) Rate effectively. Further, the EMC behavior is improved due to the shortened measurement path, which results from having fewer interconnections.

In particular, the at least one tenon 62 and the at least one elevation 64 may be formed by coining, stamping, pressing, punching, or embossing and thereby plastically deforming the solid electrical conductor 22. Hence, the above-mentioned requirement for the material ductility for the solid electrical conductor 22 is set.

The joint 3 comprises the electrically conductive lining 34 and the tenon 62, which is pressed in into the through-hole 26 and is in frictional as well as in electrical contact with the electrically conductive lining 34.

The at least one tenon 62 may be a pillar-shaped, pin-shaped, prism-shaped, pole-shaped and/or post-shaped finger 66 or protrusion 68. As such, the at least one tenon 62 may protrude from the top side 60 of the solid electrical conductor 22 along an axial direction 114. A tip of each tenon 62 may be flush with a top side of the printed circuit board 20 or may even project or stick out from the top side of the printed circuit board 20. Alternatively, the tip of each tenon 62 may be located within the corresponding through-hole 26, without sticking out.

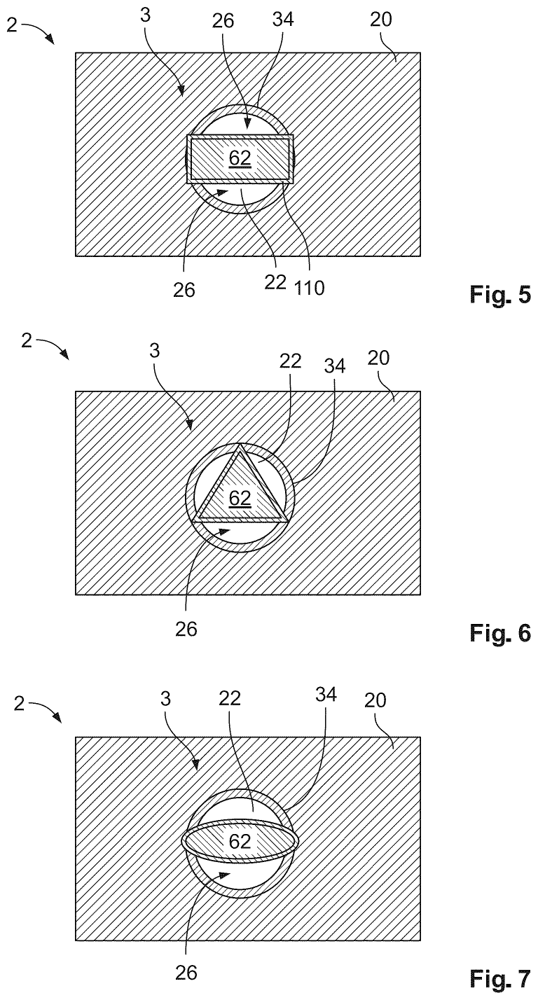

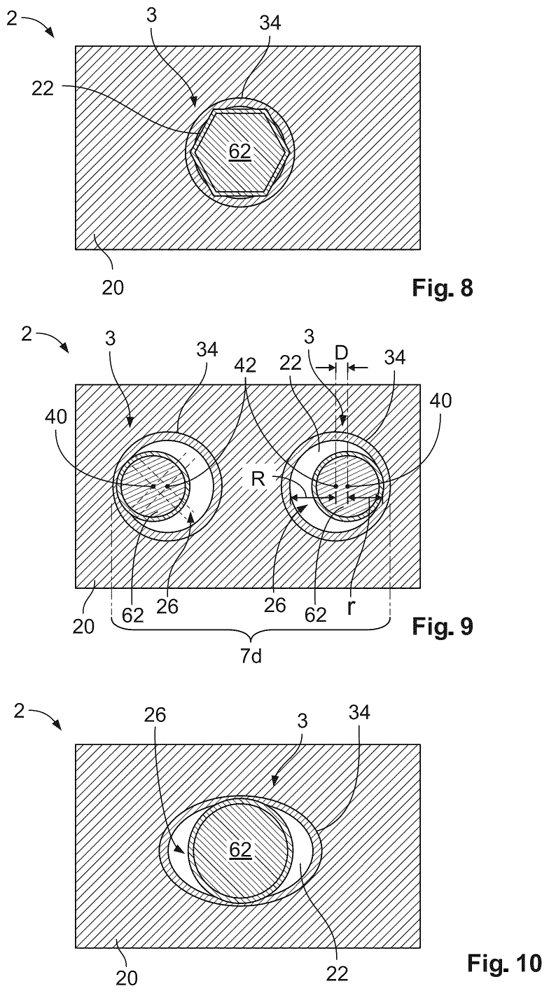

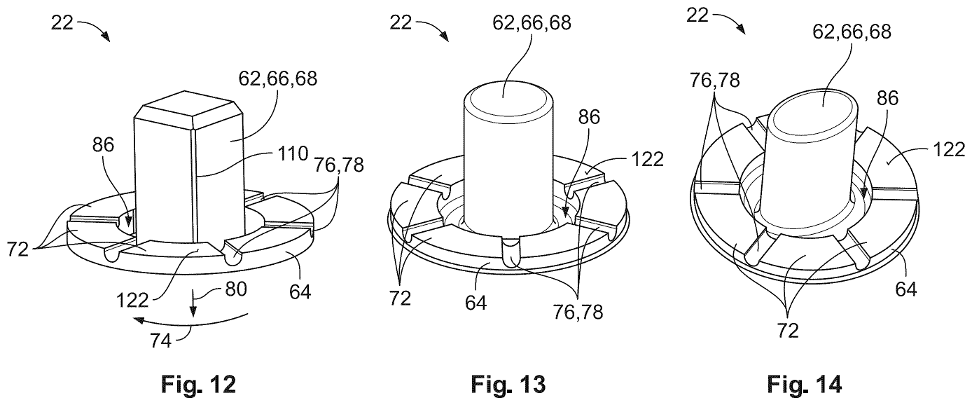

Further, the at least one tenon 62 may have a non-circular or circular cross section. For example, the at least one tenon 62 may have a square (see FIG. 4), rectangular (see FIG. 5), triangular (see FIG. 6), elliptical (see FIG. 7), polygonal (see FIG. 8) or circular (see FIGS. 9 and 10) cross-section. For example, an outer contour of the at least one tenon 62 may be a cube (see FIG. 12), a cylindrical (see FIG. 13) or an elliptical cylinder (see FIG. 14). Alternatively, the non-circular cross section of the tenon may have the shape of an oval, clover, cross or any other non-circular regular or irregular geometric form. Accordingly, the at least one through-hole 26 may have a circular or non-circular cross section, in particular for an inner contour.

As can be seen in the respective top views of FIGS. 4 to 10, in any given cross section of the tenon 62 that is perpendicular to the axial direction 114 of the tenon 62, the tenon 62 only 100 engages the lining 34 frictionally and electrically in sections. In other sections 102 of that same cross section, the lining 34 and the tenon 62 may be spaced apart and distanced from each other. This concentrates and increases the acting normal force at the locations of engagement between the tenon 62 and lining 34.

The at least one elevation 64 may extend continuously around the at least one tenon 62. For example, the at least one elevation 64 may be a ring-shaped bulge 70 on the top side 60 of the solid electrical conductor 22 encircling the at least one tenon 62 (see FIG. 2). As such, the at least one elevation 64 may form a substantially flat contact surface 122 for the at least one electrically conductive trace 44.

Alternatively, the at least one elevation 64 may extend discontinuously around the at least one tenon 62. For example, the at least one elevation 64 may be distributed around the at least one tenon 62 in the form of multiple ring segments 72 (see FIGS. 12 to 14). The ring segments 72 may be distributed in a circular arrangement and evenly spaced apart from each other in a circumferential direction 74 with respect to the at least one tenon 62. Moreover, the ring segments 72 may be mutually coplanar and jointly form the contact surface 122. Between individual ring segments 72, slits 76 or notches 78 extend through the at least one elevation 64 along a radial direction 80 with respect to the at least one tenon 62. Instead of the ring segments 72, convex knobs with a dome shape, spike shape, pyramid shape, cylinder shape, star shape or any other convexly protruding shape may be distributed around the at least one tenon 62. Multiple slits may be distributed in regular or irregular distances around the at least one elevation 64 along a circumferential direction with respect to the at least one tenon 62. The slits may separate the at least one elevation 64 into multiple ring segments 72, resulting in the discontinuously extending elevation.

In an embodiment, each knob defines a discrete contact point for the at least one electrically conductive trace 44. The knobs are distributed in a circular arrangement and evenly or unevenly spaced apart from each other in a circumferential direction with respect to the at least one tenon 62. Moreover, the contact points may be mutually coplanar. This improves the positional stability of the printed circuit board 20. Accordingly, the at least one electrically conductive trace 44 may extend discontinuously around the at least one through-hole 26, in particular around an opening of the at least one through-hole 26 on the above-mentioned bottom side 32 of the printed circuit board 20.

As can be seen in FIG. 2, the solid electrical conductor 22 may comprise at least one indent 82 on a bottom side 84 of the solid electrical conductor 22 facing away from the printed circuit board 20. More specifically, the at least one indent 82 is located opposite of the at least one tenon 62 and of the at least one elevation 64 with respect to the solid electrical conductor 22. This is a result of material displacement during the monolithic formation of the at least one tenon 62 and the at least one elevation 64 from the material of the solid electrical conductor 22. The at least one indent 82 creates a blind hole in the solid electrical conductor 22. This is a result of material displacement during the monolithic formation of the at least one tenon 62 from the material of the solid electrical conductor 22.

In an embodiment, a groove 86 is formed on the solid electrical conductor 22 between the at least one tenon 62 and the at least one elevation 64 (see FIG. 12). Said groove 86 may be circular and/or annular and may extend around the at least one tenon 62 in the circumferential direction 74 with respect to the at least one tenon 62. In the radial direction 80 with respect to the at least one tenon 62, the groove 86 may separate the at least one tenon 62 and the at least one elevation 64 from each other. Thereby, the groove 86 serves as a relief groove or undercut allowing the printed circuit board 20 to be fully seated against the shoulder formed by the at least one elevation 64.

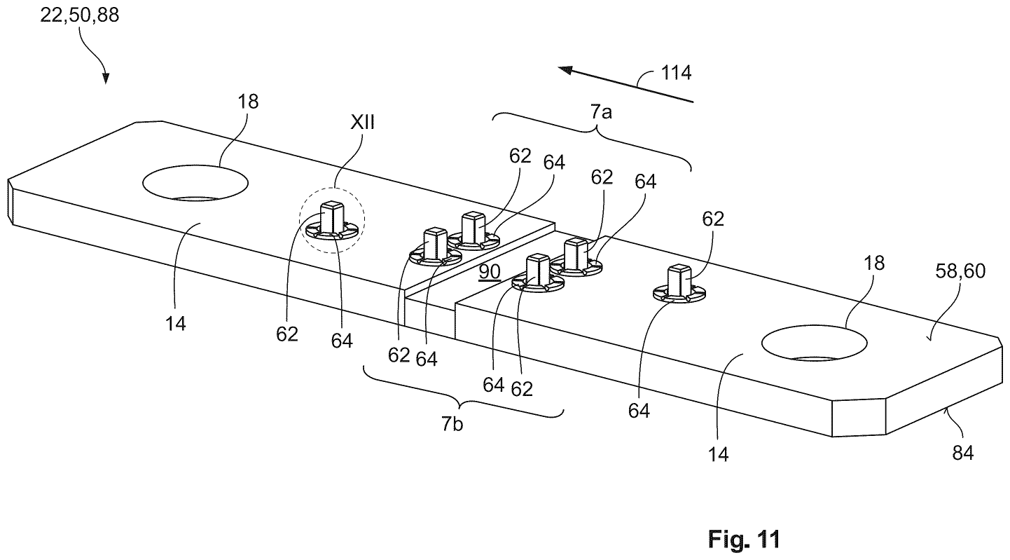

In the shown embodiment of FIG. 11, the solid electrical conductor 22 may be a shunt resistor 88 with at least one resistive element 90 and at least one connection terminal 14 adjacent to the at least one resistive element 90. In an embodiment, the shunt resistor 88 comprises two connection terminals 14 with the resistive element 90 located in between. The at least one tenon 62 and the at least one elevation 64 may be monolithically formed from the material of the resistive element 90 or the connection terminals 14. As such, the electrical assembly 2 of this embodiment can be utilized in an active shunt for the measurement of electrical currents.

The connection terminals 14 may be made of the same materials as already mentioned for the solid electrical conductor 22. The resistive element 90 may be comprised of or consist of resistance alloys, which are conventionally known under names such as Manganin, Constantan, Isaohm or any other conductive material with a low thermal variation of its resistivity. The at least one connection terminal 14 may be configured as a terminal plate. Further, the at least one connection terminal 14 may comprise at least one screw hole to connect the shunt resistor 88 to the circuit of which the current values are to be measured. The shunt resistor 88 usually has a relatively low resistance, so that essentially all current to be measured flows through the shunt resistor 88.

The shunt resistor 88 can be arranged in a circuit in parallel with the voltmeter 92 in order to be used in the active shunt 6 already mentioned above. To achieve the parallel arrangement, the shunt resistor 88 may comprise a pair of tenons 62 and a pair of elevations 64. In an embodiment, one tenon 62 of the pair and one elevation 64 of the pair are positioned on each of two opposite sides of the resistive element 90. The voltmeter 92 is connected through the printed circuit board 20 with the tenons 62 and elevations 64 such that the resistive element 90 is parallel with the voltmeter 92.

The indent 82 can reach a depth of up to 80% of the material thickness of the solid electrical conductor 22 and form the blind hole. Consequently, the effect of a so-called current shadow is possible. In particular, the at least one indent 82 creates a choke point that forces the electric current to flow as close as possible to the tenon on the opposite side of the shunt resistor 88 described below.

The voltage across the shunt resistor 88 is proportional to the current flowing through it and thus, the measured voltage can be scaled to directly display the current value. Therefore, the concrete resistance of the shunt resistor 88 is chosen so that the resultant voltage drop is high enough to be measurable with the voltmeter 92, but low enough not to disrupt the circuit.

For accurate scaling, the actual resistance value of the shunt resistor 88 has to be known as precisely as possible, since it influences the proportionality factor between the measured voltage and the current value. For this purpose, the resistance value of the resistive element 90 needs to have a minimal temperature coefficient. That is, the resistance value of the resistive element 90 should be virtually independent of the (operating) temperature. This is important, since electrical circuits, especially resistors, tend to heat up under load.

In particular, each tenon 62 extends into one through-hole 26 of the printed circuit board 20, which comprises the necessary number of through-holes 26. Here, the through-holes 26 function as mortises and create the joints 3 with the corresponding tenons 62. Simultaneously, the electrically conductive linings 34 of the through-holes 26 enter into electrical contact with the corresponding tenons 62. If present, each elevation 64 is in electrical contact with one electrically conductive trace 44 of the printed circuit board 20, which comprises the necessary number of traces 44.

As shown in FIGS. 2 to 4, the at least one tenon 62 may be engaged in a press-fit connection 106 with the printed circuit board 20 at the at least one through-hole 26. Optionally, the press-fit connection 106 is obtained by a so-called massive press fit. For this purpose, the at least one tenon 62 may have a slightly over-sized non-circular cross section and the at least one through-hole 26 may have a slightly under-sized circular cross section. This deliberate mismatch between the shapes and sizes of the cross sections can be best seen in FIGS. 4 to 8. It is also conceivable that the at least one through-hole 26 has a non-circular cross section, while the at least one tenon 62 has a circular cross section (see FIG. 10).

With this mismatch in place, the at least one tenon 62 is forced into the at least one through-hole 26, as is depicted with arrows 108 in FIG. 2. In an embodiment, the at least one tenon 62 comprises at least one edge 110 that incises into the electrically conductive lining 34 of the at least one through-hole 26. The at least one edge 110 may be a cutting edge and/or may extend along an axial direction with respect to the tenon 62. With the at least one edge 110, an oxide layer can be scraped away when the joint 3 is created. In the course of this massive press fit, the electrically conductive lining 34 of the at least one through-hole 26 is at least in sections cold-welded with the at least one tenon 62. This renders the electrical contact within the joint 3 gastight. In particular, no oxide layer can be formed between the lining 34 and the tenon 62 in the cold-welded sections.

The electrically conductive lining 34 in the through-hole 26 functions as a mortise, with which the tenon 62 frictionally engages, effecting a mechanical connection between the printed circuit board 20 and the solid electrical conductor 22. At the same time, the electrically conductive lining 34 and the tenon 62 provide contact surfaces, which are in mutual electrical contact, establishing an electrical connection between the printed circuit board 20 and the solid electrical conductor 22.

According to another possible embodiment shown in FIG. 9, the at least one tenon 62 may be arranged eccentrically with respect to the at least one through-hole 26 and may one-sidedly engage with the electrically conductive lining 34 of the at least one through-hole 26. This way, the tenon 62 does not have to fill up the entire cross section of the through-hole 26 and less material is required. In particular, a distance D by which a middle axis 40 of the at least one tenon 62 is shifted from a middle axis 42 of the at least one through-hole 26 may be equal to or larger than the difference between the inner radius R of the at least one through-hole 26 and the outer radius r of the at least one tenon 62 (D≥R−r).

In this case, the circularity of the cross section of the at least one tenon 62 and the at least one through-hole 26 is irrelevant. However, it must be ensured that the printed circuit board 20 cannot “shift back” relative to the solid electrical conductor 22. For example, at least one pair 7d of tenons 62 and through-holes 26 are provided, wherein the middle axes 40 of the tenons 62 are shifted in mutually opposite directions from the middle axes 42 of the through-holes 26 (see FIG. 9). Alternatively, if only one tenon and one through-hole are present, the aforementioned housing 8 may guarantee that the printed circuit board and the solid electrical conductor are fixated in their relative position, such that the at least one tenon is arranged eccentrically with respect to the at least one through-hole.

As suggested above, two or more tenons 62 may be formed on the solid electrical conductor 22, wherein each tenon 62 may be surrounded by an elevation 64 formed on the solid electrical conductor 22. Accordingly, the printed circuit board 20 may comprise two or more through-holes 26 optionally surrounded by electrically conductive traces 44 at respective locations corresponding with locations of the tenons 62 and elevations 64.

From FIG. 11 it can be seen that the two or more tenons 62 may be mutually parallel. The two or more through-holes 26 likewise may extend parallel to each other. The elevations 64 may be mutually coplanar, just like the electrically conductive traces 44 are mutually coplanar. This allows the printed circuit board 20 to be attached to the solid electrical conductor 22 at multiple locations. Not only is the mechanical stability of each joint 3 increased this way, but also electrical connections are obtained at multiple locations, which can be utilized for certain electrical measurement applications, as will be described in further detail below.

In an embodiment, at least two pairs 7a, 7b of tenons 62 and elevations 64 may be formed on the solid electrical conductor 22. Accordingly, at least two pairs of through-holes and conductive traces may be provided on the printed circuit board. In particular, the tenons 62 and elevations 64 of one pair 7a may have the same distance to each other as the tenons 62 and elevations 64 of the other pair 7b. Likewise, the through-holes and conductive traces of one pair may have the same distance to each other as the through-holes and conductive traces of the other pair. The tenons and elevations as well as the through-holes and conductive traces of each pair may be aligned along an axial direction 114 of the solid electrical conductor 22. The at least two pairs of joints 3 establish a certain redundancy for electrical measurement applications.

To directly implement temperature compensation, the electrical assembly 2 may comprise a temperature sensor 116 arranged on the above-mentioned bottom side 32 of the printed circuit board 20 facing the solid electrical conductor 22, as shown in FIGS. 2 and 3. The temperature sensor 116 may be in thermal contact with the solid electrical conductor 22 directly and/or via a thermal paste 118 (see FIG. 3). The measured temperatures of the temperature sensor 116 may be read by the electrical measurement device 1 for the purpose of the temperature compensation.

The shunt resistor 88 as a whole (including all of its remaining components, such as the connection terminals) exhibits a certain temperature dependency on its overall resistance value. Therefore, temperature will inevitably have an undesired impact on the measurement results of the current value. To overcome this issue, temperature compensation can be applied.

Since, according to the present invention, no separate connection element is arranged between the printed circuit board 20 and the solid electrical conductor 22, the printed circuit board 20 and the solid electrical conductor 22 are relatively close to each other. This allows for the use of surface mount devices (SMD) for the temperature sensor 116. In particular, one or more negative temperature coefficient (NTC) thermistors 120 may be surface mounted to the bottom side 32 of the printed circuit board 20 facing the solid electrical conductor 22.

The electrical sensor 4 of the electrical measurement device 1 is connected to the electrically conductive lining 34 of the at least one through-hole 26 of the printed circuit board 20. This is shown in FIG. 1. For example, the electrically conductive lining 34 may be connected with e.g., a sensor probe, a sensor wire and/or an internal printed circuit board of the electrical sensor 4. Like the electrical assembly 2, the electrical measurement device 1 also benefits from the above-explained technical effects and advantages of the joint 3. In particular, the electrical sensor connected to the electrically conductive lining 34 can be used to measure the electrical values of the solid electrical conductor 22 of which at least one tenon 62 is in electrical contact with the lining 34.

Lastly, a method for the manufacturing of the electrical assembly 2 is explained:

First, a substantially flat solid electrical conductor and a printed circuit board 20 with at least one through-hole 26 having an electrically conductive lining 34 within the at least one through-hole 26 are provided.

The solid electrical conductor 22 is coined to monolithically form, from the material of the solid electrical conductor, at least one tenon 62 (see FIG. 2). This coining procedure may involve stamping, pressing, punching and/or embossing the solid electrical conductor 22. Moreover, a staged tool and/or a progressive tool may be used for this coining procedure to achieve a high shape accuracy when forming the tenon 62. Optionally, the at least one tenon 62 may have slightly slanted outer surfaces like a truncated cone or pyramid to facilitate exit from the coining tool. The slant angle may range from 0.1º to 1°.

Thereafter, the at least one tenon 62 is inserted into the at least one through-hole 26. This insertion procedure involves pressing in or press-fitting the at least one tenon 62 into the at least one through-hole 26. Thereby, the at least one tenon 62 is brought into electrical contact with the electrically conductive lining 34 of the at least one through-hole 26 (see FIG. 3).

Compared to other manufacturing methods of comparable electrical assemblies, the inventive method produces less scrap and involves less parts, since the at least one tenon 62 is formed by coining in a chipless manner. Further, the resulting electrical assembly 2 comprises at least one joint 3 exhibiting the advantages and functions explained above.

Any references to standards made in the present disclosure are to be understood as pointing to the latest version of the respective standard at the application date of the present disclosure.

What is claimed is:

1. A joint for attaching a printed circuit board to an electrical conductor, comprising:
an electrically conductive lining that lines an inner surface of a through-hole in the printed circuit board; and
a tenon pressed in the through-hole, the tenon is in frictional and electrical contact with the electrically conductive lining, the tenon is monolithically formed from a material of the electrical conductor.

2. The joint of claim 1, wherein the electrically conductive lining and the tenon are sectionally cold welded to each other.

3. The joint of claim 1, wherein the tenon has an edge incising into the electrically conductive lining.

4. The joint of claim 1, wherein at least one of the tenon and the electrically conductive lining has a non-circular cross-section.

5. The joint of claim 1, wherein the tenon is arranged eccentrically with respect to the electrically conductive lining.

6. An electrical assembly for an electrical measurement device, comprising:
an electrical conductor having a tenon monolithically formed from a material of the electrical conductor; and
a printed circuit board having a through-hole lined with an electrically conductive lining, the tenon at least sectionally extends into the through-hole and is in frictional and electrical contact with the electrically conductive lining at a joint.

7. The electrical assembly of claim 6, wherein the electrical conductor is a solid electrical conductor.

8. The electrical assembly of claim 7, wherein the electrical conductor has an indent on a bottom side of the electrical conductor facing away from the printed circuit board.

9. The electrical assembly of claim 8, wherein the indent is opposite the joint with respect to the electrical conductor.

10. The electrical assembly of claim 6, wherein the electrically conductive lining is formed by at least one of a plating, a coating, and an insert sleeve.

11. The electrical assembly of claim 10, wherein an inner cross section of the insert sleeve has a shape of a square, rectangle, triangle, polygon, oval, ellipse, clover, cross or any other non-circular regular or irregular geometric form.

12. The electrical assembly of claim 6, wherein the printed circuit board has a substrate made of glass-reinforced epoxy laminate material.

13. The electrical assembly of claim 6, further comprising a temperature sensor arranged on a bottom side of the printed circuit board facing the electrical conductor.

14. The electrical assembly of claim 6, wherein the electrical conductor is a shunt resistor with a resistive element.

15. The electrical assembly of claim 14, wherein the shunt resistor has a connection terminal arranged adjacent to the resistive element.

16. An electrical measurement device, comprising:
an electrical assembly including an electrical conductor having a tenon monolithically formed from a material of the electrical conductor and a printed circuit board having a through-hole lined with an electrically conductive lining, the tenon at least sectionally extends into the through-hole and is in frictional and electrical contact with the electrically conductive lining at a joint; and
an electrical sensor connected to the electrically conductive lining.

17. A method for the manufacturing of an electrical assembly, comprising:
providing an electrical conductor and a printed circuit board, the printed circuit board having a through-hole;
lining the through-hole with an electrically conductive material;
coining the electrical conductor to monolithically form a tenon from a material of the electrical conductor; and
pressing the tenon into the through-hole to establish a frictional and electrical connection between the tenon and the electrically conductive material.

18. The method of claim 17, wherein the electrical conductor is solid and has a flat side prior to the coining step.

19. An electrical conductor, comprising:
a tenon formed by plastically deforming a material of the electrical conductor.
